(19) United States
(12) Patent Application Publication
(10) Pub. No.: US 2023/0311269 A1
(43) Pub. Date: Oct. 5, 2023

(54) CMP POLISHING PAD WITH PROTRUDING STRUCTURES HAVING ENGINEERED OPEN VOID SPACE

(71) Applicant: Rohm and Haas Electronic Materials CMP Holdings, Inc., Newark, DE (US)

(72) Inventors: John R. McCormick, Exton, PA (US); Bryan E. Barton, Lincoln University, PA (US)

(21) Appl. No.: 18/331,418

(22) Filed: Jun. 8, 2023

Related U.S. Application Data
(62) Division of application No. 16/829,024, filed on Mar. 25, 2020.

(51) Int. Cl. B24B 37/26; B24B 37/30; B24B 37/11

(52) U.S. Cl. CPC B24B 37/26; B24B 37/30; B24B 37/11

(57) ABSTRACT

A polishing pad useful in chemical mechanical polishing comprises a base pad having a top side, and a plurality of protruding structures on the top side of the base pad, each of the protruding structures having a body, where the body has (i) an exterior perimeter surface defining an exterior shape of the protruding structure, (ii) an interior surface defining a central cavity and (iii) a top surface defining an initial polishing surface area, wherein the body further has openings in it from the cavity to the exterior perimeter surface.

### FIELD OF THE INVENTION

The present invention relates generally to the field of polishing pads for chemical mechanical polishing. In particular, the present invention is directed to a chemical mechanical polishing pad having a polishing structure useful for chemical mechanical polishing of magnetic, optical and semiconductor substrates, including front end of line (FEOL) or back end of line (BEOL) processing of memory and logic integrated circuits.

### BACKGROUND

In the fabrication of integrated circuits and other electronic devices, multiple layers of conducting, semiconducting and dielectric materials are deposited onto and partially or selectively removed from a surface of a semiconductor wafer. Thin layers of conducting, semiconducting and dielectric materials may be deposited using a number of deposition techniques. Common deposition techniques in modern wafer processing include physical vapor deposition (PVD), also known as sputtering, chemical vapor deposition (CVD), plasma-enhanced chemical vapor deposition (PECVD) and electrochemical deposition (ECD), among others. Common removal techniques include wet and dry etching; isotropic and anisotropic etching, among others.

As layers of materials are sequentially deposited and removed, the uppermost surface of the wafer becomes non-planar. Because subsequent semiconductor processing (e.g., photolithography, metallization, etc.) requires the wafer to have a flat surface, the wafer needs to be planarized. Planarization is useful for removing undesired surface topography and surface defects, such as rough surfaces, agglomerated materials, crystal lattice damage, scratches and contaminated layers or materials. In addition, in damascene processes a material is deposited to fill recessed areas created by patterned etching but the filling step can be imprecise and overfilling is preferable to underfilling of the recesses. Thus, material outside the recesses needs to be removed.

Chemical mechanical planarization, or chemical mechanical polishing (CMP), is a common technique used to planarize or polish workpieces such as semiconductor wafers and to remove excess material in damascene processes. In conventional CMP, a wafer carrier, or polishing head, is mounted on a carrier assembly. The polishing head holds the wafer and positions the wafer in contact with a polishing surface of a polishing pad that is mounted on a table or platen within a CMP apparatus. The carrier assembly provides a controllable pressure between the wafer and polishing pad. Simultaneously, a slurry or other polishing medium is dispensed onto the polishing pad and is drawn into the gap between the wafer and polishing layer. To effect polishing, the polishing pad and wafer typically rotate relative to one another. As the polishing pad rotates beneath the wafer, the wafer traverses a typically annular polishing track, or polishing region, wherein the wafer's surface directly confronts the polishing layer. The wafer surface is polished and made planar by chemical and mechanical action of the polishing surface and polishing medium (e.g., slurry) on the surface.

The interaction among polishing layers, polishing media and wafer surfaces during CMP has been the subject of increasing study, analysis, and advanced numerical modeling in the past years in an effort to optimize polishing pad designs. Most of the polishing pad developments since the inception of CMP as a semiconductor manufacturing process have been empirical in nature, involving trials of many different porous and non-porous polymeric materials and mechanical properties of such materials. Some approaches involve providing a polishing pad with various protruding structures extending from the base of the pad—See, e.g. U.S. Pat. Nos. 6,817,925; 7,226,345; 7,517,277; 9,649,742; U.S. Pat. Pub. No. 2014/0273777; U.S. Pat. No. 6,776,699. Other approaches use lattice structures that can form a generally monolithic structure having voids. See e.g. U.S. Pat. Nos. 7,828,634, 7,517,277; or 7,771,251. CN 20190627407 discloses a polishing structure with recess portions and protrusions that are hollow where the hollow region can be opened at the top by removal of the top surface of the protrusion during polishing. The top opening can allow for collection of slurry particles and polishing debris that can lead to polishing defects.

U.S. 2019/0009458 discloses use of additive manufacturing (i.e. 3D printing) to make complex single unitary structures such as those having (a) a body portion having a surface portion thereon; (b) at least a first array of feature elements formed on said surface portion, each of said feature elements comprising: (i) a support structure connected to said surface portion and extending upward therefrom; and (ii) a top segment connected to said support structure, said top structure and said support structure together defining an internal cavity formed therein. These structures are disclosed as collapsing under pressure and then returning to a previous configuration. The structures are disclosed as being useful for noise and vibration isolation and skin body contact applications.

### SUMMARY OF THE INVENTION

Disclosed herein is a polishing pad useful in chemical mechanical polishing comprising a base pad, and a plurality of protruding structures on the base pad, each of the protruding structures having a body, where the body has (i) an exterior perimeter surface defining an exterior shape of the protruding structure, (ii) an interior surface defining one or more central cavity and (iii) a top surface defining an initial polishing surface area, wherein the body further has openings in it from the cavity to the exterior perimeter surface.

Also disclosed is a method of polishing using such a polishing pad.

### BRIEF DESCRIPTION OF THE DRAWINGS

FIG. 1 is drawing of an example of a protruding structure as can be used in the pad of this invention.

FIG. 2 is drawing of an example of a protruding structure as can be used in the pad of this invention.

FIG. 3 is drawing showing a base pad with an arrangement of protruding structures as can be used in the pad of this invention.

FIG. 4 is a drawing showing a portion of a polishing pad having a base pad with an example of protruding structures thereon.

FIG. 5 is a graph showing calculated predicted deflection of a solid protruding structure as compared to a protruding structure having the cavity and openings as disclosed herein.

FIG. 6 is a planarized view of the exterior perimeter of an exemplary protruding structure showing alignment of openings.

FIG. 7 is a plot of removal rate for a polishing pad having solid protrusions versus protrusions with cavity and openings as disclosed herein.

### DETAILED DESCRIPTION OF THE INVENTION

The polishing pad as disclosed herein includes a base pad having thereon a plurality of protruding structures. The protruding structures have at least one central cavity open at the top of the structure and have openings from the cavity to the exterior perimeter of the protruding structure (i.e. side openings or wall openings).

Such pads can provide certain advantages. Specifically, the design presents a relatively high surface polishing surface area (also referred to as contact area as this is the portion of the pad that contacts the surface to be polished) while the void(s) (e.g. the cavity and/or the openings) enable good management/transport of polishing fluids that are typically used. This fluid management feature can help control temperature—e.g. reducing or limiting the increase in temperature due to frictional heating during polishing. The lower polishing temperatures can help preserve mechanical properties of the polishing pad and can help avoid irreversible thermally induced chemical reactions in the pad or the substrate being polished. Chemical reactions in the pad can increase the likelihood of defect generations during polishing.

With the central cavity and the side openings in the body (or wall openings) of the protrusion, there can be efficient displacement of the fluid between the wafer and the protruding structure, thus reducing the time to contact between the pad and the substrate to be polished. This can increase the time the polishing surface is in contact with the wafer and increase the number of polishing protrusions in contact, either of which can potentially produce higher removal rates (higher asperity contact efficiencies and reduced defectivity (reduced individual asperity contact pressure). For example, the novel structures approach a surface at a faster rate than do their solid counterpart as shown in Table 1 where speed of approach of the feature to a substrate is shown.

Velocity @ 2.6 μm separation (m/s)

| Radius, mm | Novel (m/s) | Solid (m/s) | Ratio |
|---|---|---|---|
| 0.125 | 0.4100 | 0.0340 | 12.1 |
| 0.25 | 0.2770 | 0.0690 | 39.1 |
| 0.5 | 0.1200 | 0.0017 | 70.6 |

The use of voids can enable a pad having a harder or higher modulus top polishing surface to be applied to the substrate to be polished, while having a lower overall compressive modulus. The lower modulus can improve conformation of the pad to the substrate to be polished. For example, the effective compressive modulus of the pad can a be at least 0.1, at least 1, at least 10, at least 20 or at least 25% up to 100, up to 90, up to 80, up to 70, up to 60, up to 50 or up to 40% of the modulus of a pad made with solid protrusions having the same exterior dimensions and the same material used in making the protruding structures disclosed herein. The effective compressive modulus of the pad can be determined using a modified version of ASTM D3574 wherein since the specified thickness of 0.49 inches cannot be achieved by the deflection rate is slowed from the specified 0.5 inch/minute to a rate of 0.04 inches/minutes and the cross-section area of compression is reduced from 1 square inch to 0.125 square inches to reduce the effect of sample thickness variation and curl. Additional capacitance sensors can be added to more accurately measure the strain at a given stress. Effective modulus of the pad as measured according to this method can be at least 0.1, at least 1, at least 5, at least 10, at least 20, at least 40, at least 50, at least 70, or at least 100 megaPascals (MPa) up to 5, or up to 1 gigaPascals (GPa), or up to 700, up to 500, up to 300 MPa.

The protruding structures having cavity and side body openings (i.e., wall openings) can be more robust mechanically in that they show less deflection than a solid protruding structure of equivalent diameter. Equivalent diameter, D, is calculated as equivalent diameter, D, is calculated as

D=2*[square root of {(Initial polishing surface area)/π}].

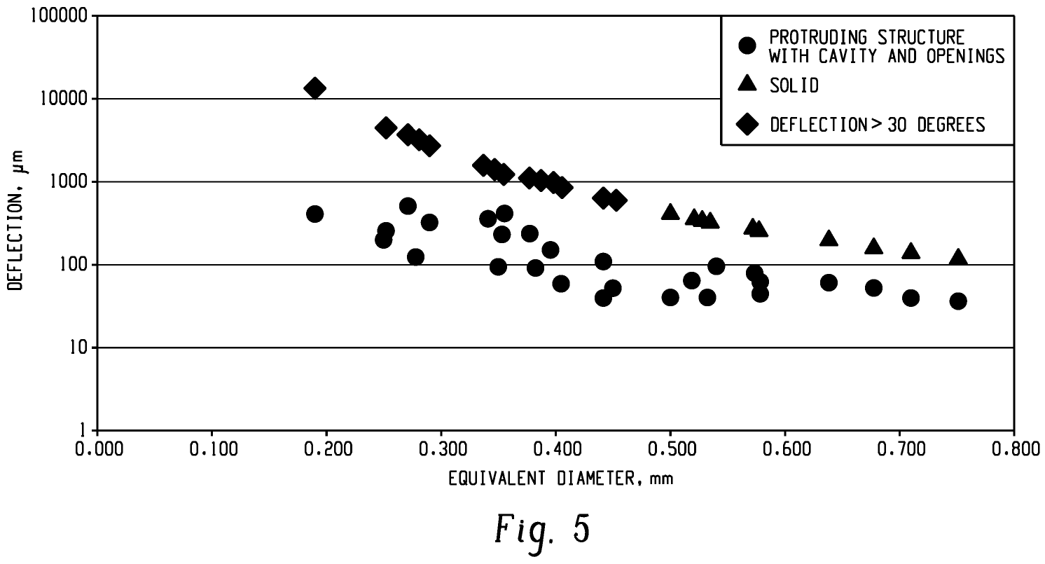

Thus, if initial polishing surface area for a protruding structure is 28.3, a cylindrical structure having a diameter of 3 would be a solid structure of equivalent diameter regardless of the diameter of the protruding structure having the voids as disclosed herein. Calculated deflection of solid protruding structures as compared to protruding structures having the cavity and openings as disclosed herein are shown in FIG. 5. For FIG. 5 the structures were cylindrical with a height of 0.125 inches (0.635 cm) and an applied pressure of 5 pounds per square inch (psi) or 34.5 kPa. This demonstrates that the structures as disclosed herein have stronger mechanical properties for an equivalent diameter than do solid protruding structures. For solid protruding structures at diameter of less than 0.5 millimeters (mm), the deflection could not be calculated accurately but is believed to continue the upward trend shown for the solid protruding structures of 0.5 mm or more.

The pads with protruding structures having the void design recited herein can have a substantially consistent polishing area as the protrusion is worn down during use when the size and orientation of the wall openings are selected to ensure such consistency.

### Base Pad

The polishing pad disclosed herein includes a base pad having protruding structures thereon.

The base pad or base layer can be a single layer or can comprise more than one layer. The top surface of the base pad can define a plane, in the x-y Cartesian coordinates. The base may be provided on a subpad. For example, the base layer may be attached to a subpad via mechanical fasteners or by an adhesive. The subpad can be made from any suitable material, including for examples the materials useful in the base layer. The base layer in some aspects can have a thickness of at least 0.5 or at least 1 mm. The base layer in some aspects can have a thickness of no more than 5, no more than 3, or no more than 2 mm. The base layer can be provided in any shape, but it can be convenient to have a circular or disc shape with a diameter in the range of at least 10, at least 20, at least 30, at least 40, or at least 50 centimeters (cm) up to 100, up to 90, or up to 80 cm.

The base pad or base layer may comprise any material known for use as base layers for polishing pads. For example, it can comprise a polymer, a composite of a polymeric material with other materials, ceramic, glass, metal, stone or wood. Polymers and polymer composites can be used as the base pad, particularly for the top layer if there is more than one layer, due to compatibility with the material that can form the protruding structures. Examples of such composites include polymers filled with carbon or inorganic fillers and fibrous mats of, for example, glass or carbon fibers, impregnated with a polymer. The base of the pad can be made of a material having one or more of the following properties: a Young's modulus as determined, for example, by ASTMD412-16 in the range of at least 2, at least 2.5, at least 5, at least 10, or at least 50 MPa up to 900, up to 700, up to 600, up to 500, up to 400, up to 300, or up to 200 MPa. The based pad can be made of a material having a compressive modulus according to ASTM D3574 in the range of at least 2, at least 2.5, at least 5, at least 10, or at least 50 MPa up to 900, up to 700, up to 600, up to 500, up to 400, up to 300, or up to 200 MPa. The based pad can be made of a material having a Poisson's ratio as determined, for example, by ASTM E132015 of at least 0.05, at least 0.08, or at least 0.1 up to 0.6 or up to 0.5; a density of at least 0.4 or at least 0.5 up to 1.7, up to 1.5, or up to 1.3 grams per cubic centimeter (g/cm³).

Examples of such polymeric materials that can be used in the base pad include polycarbonates, polysulfones, nylons, epoxy resins, polyethers, polyesters, polystyrenes, acrylic polymers, polymethyl methacrylates, polyvinylchlorides, polyvinyl fluorides, polyethylenes, polypropylenes, polybutadienes, polyethylene imines, polyurethanes, polyether sulfones, polyamides, polyether imides, polyketones, epoxies, silicones, copolymers thereof (such as, polyether-polyester copolymers), and combinations or blends thereof.

The polymer can be a polyurethane. The polyurethane can be used alone or can be a matrix for carbon or inorganic fillers and fibrous mats of, for example glass or carbon fibers. For purposes of this specification, “polyurethanes” are products derived from difunctional or polyfunctional isocyanates, e.g. polyetherureas, polyisocyanurates, polyurethanes, polyureas, polyurethaneureas, copolymers thereof and mixtures thereof. The CMP polishing pads in accordance may be made by methods comprising: providing the isocyanate terminated urethane prepolymer; providing separately the curative component; and combining the isocyanate terminated urethane prepolymer and the curative component to form a combination, then allowing the combination to react to form a product. It is possible to form the base pad or base layer by skiving a cast polyurethane cake to a desired thickness. Optionally, preheating a cake mold with IR radiation, induction or direct electrical current can reduce product variability when casting porous polyurethane matrices. Optionally, it is possible to use either thermoplastic or thermoset polymers. The polymer can be a crosslinked thermoset polymer.

### Protruding Structures

The protruding structures are on and protrude from the base pad. They project in the z-direction from xy-plane defined by the top surface of the base pad. The protruding structures can be orthogonal (perpendicular) to the xy-plane defined by the base pad or they can be at an angle. They can be integral with the base pad or a top layer of the base pad or may be distinct and adhered to the base pad. They can be of the same material as the base pad or a different material from the base pad.

The protruding structures are characterized by an exterior perimeter surface defining an exterior shape of the protruding structure, an interior surface defining one or more than one central cavity and a top surface defining an initial polishing surface area, Aᵢₚₛ. The protruding structure includes openings from the exterior perimeter to the cavity. As the polishing pad is used, the protruding structures are worn down exposing new top surface to define a subsequent polishing surface having a subsequent polishing surface area, Aₛₚₛ. This happens continuously during polishing. The openings, also referred to as side holes or wall openings, can be positioned in the protruding structure such that as the protruding structure is worn down during polishing the surface that is available for polishing does not substantially vary—i.e. “substantially constant contact area”. For example, the substantially constant contact area can be defined subsequent polishing surface area, Aₛₚₛ at any time during polishing that is within 25%, or within 10% of the initial polishing surface area Aᵢₚₛ. An individual protruding structure can have substantially constant contact area.

The pad with all its protruding structures can have substantially constant contact area. For example, individual protruding structures on the pad can have contact areas (i.e. subsequent polishing surface areas) that vary by more than 25% from the initial polishing surface are if other protruding structures on the pad vary in an inverse way such that overall the pad has substantially constant contact area (i.e. cumulative subsequent polishing surface area of all the protrusions on the pad at a given point in polishing differ from cumulative initial polishing surface area by no more than 25% or no more than 10% based on cumulative initial polishing surface area.

The contact area ratio is cumulative surface contact area, A_{cpsa}, or the plurality of protruding structures divided by the area of the base, A_{b}. The cumulative surface contact area can be calculated by adding the area of the top surfaces 11 of all of the protruding structures. Since pads are conventionally circular, for a conventional pad shape π(r_{b})², where r_{b} is the radius of the pad. According to certain embodiments ratio of A_{cpsa}/A_{b} is at least 0.1, at least 0.2, at least 0.3, or at least 0.4 and is no more than 0.8, no more than 0.75, no more than 0.7, no more than 0.65, or no more than 0.6.

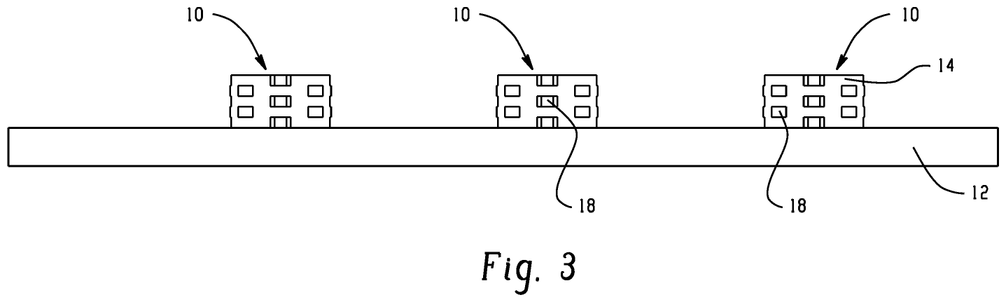

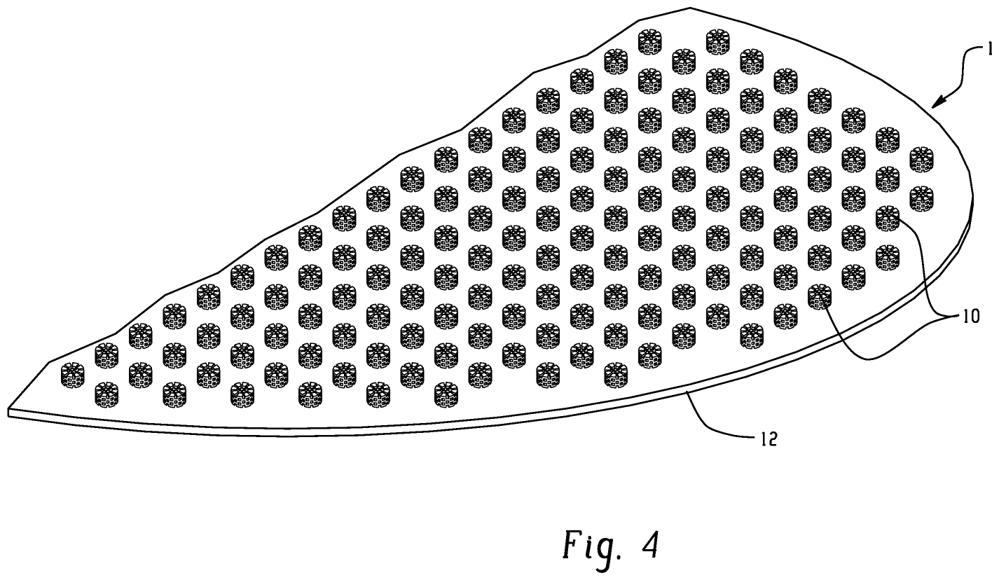

FIGS. 1, 3, and 4 show an example of a substantially cylindrical type protruding structure 10. FIGS. 3 and 4 shows three such structures 10 on a based pad 12. FIG. 4 shows a partial view of a polishing pad 1 having a base pad 12 and protruding structures 10. The protruding structure 10 has an exterior perimeter surface 14, a top polishing surface 15, interior surface 16 defining a cavity 17, and openings 18. The openings are offset from each other in the vertical and horizontal directions to provide a substantially constant contact area.

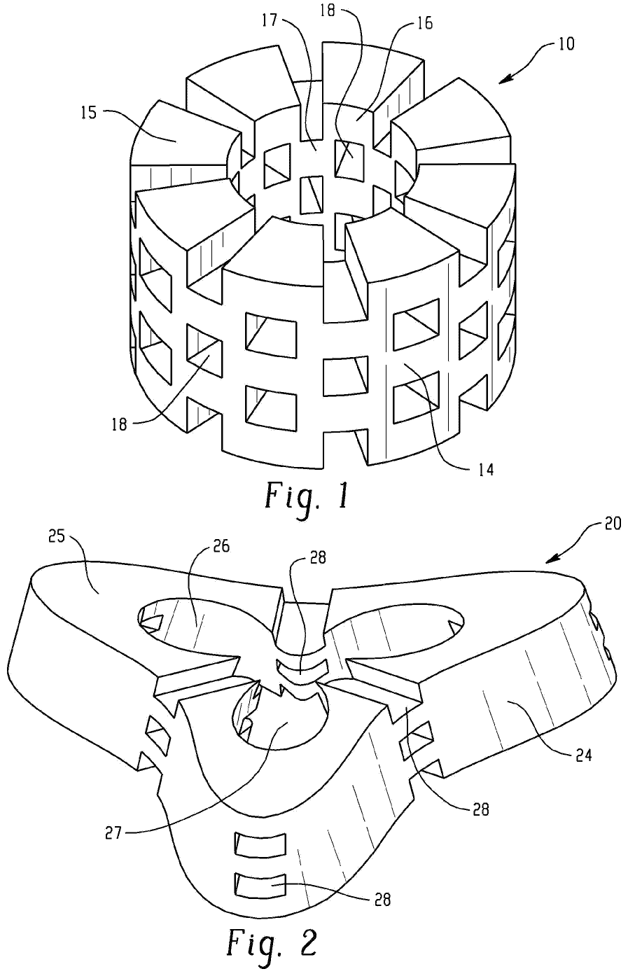

FIG. 2 shows an alternative configuration of a protruding structure 20 having lobed exterior perimeter defined by exterior perimeter 24, with offset openings 28, interior surface 26, and cavity 27.

The protruding structures can have a height of at least 0.05 or at least 0.1 mm up to 3, up to 2.5, up to 2, or up to 1.5 mm from the top surface of the base. The protruding structure can be normal or substantially orthogonal in its main axis of its height relative to the surface of the base. Alternatively, the protruding structure can be at an angle other than 90 degrees relative to the surface of the base such that it is slanted or such that the base is slightly larger or slightly smaller than the initial top surface.

The exterior shape of the protruding structure can be symmetrical or asymmetrical. Examples of regular shapes include cylinders, ovals, squares, regular polygons (equilateral triangle, pentagon, hexagon, heptagon, octagon, etc.), symmetrical lobed structures. Examples of asymmetrical shapes include irregular polygons having sides of different sizes, asymmetrical lobed structures, etc.

The exterior can be entirely convex or can include concave and convex portions. FIG. 1 shows an exterior perimeter that is convex, while FIG. 2 shows an exterior perimeter that has concave and convex portions.

The exterior perimeter can have a maximum dimension (i.e. from one point on the exterior perimeter to the furthest point on the exterior perimeter of at least 0.2, at least 0.5 mm, at least 0.7, or at least 1 mm, up to 50, up to 20, up to 10, up to 5, up to 3, or up to 2 mm. For structures that have exterior perimeters with convex and concave portions as shown for example in FIG. 2, the exterior perimeter can also have a shortest dimension of the cross section of a structure (e.g. the shortest distance a fluid would travel across the top surface of a protruding structure, for example the distance across the top surface from exterior perimeter to cavity) that can be at least 0.01, at least 0.05, at least 0.1, or at least 0.5 mm up to 5, up to 3, up to 2, or up to 1 mm.

The protruding structures include one or more cavities. The cavity can be defined by an interior surface of the protruding structure. The cavity for each protruding structure can be a single cavity or can be two or more cavities. If there are two or more cavities per protruding structure, then they may be defined by an interior surface and a supporting rib or the like. The cavity(ies) can extend the entire height of the protruding structure. The cavity can be open to the surrounding environment at the top of the protruding structure. If two or more adjacent cavities are used, then the two or more cavities can each be open to the surrounding environment at the top of the protruding structure. The cavity can be any shape. For example, the cavity may be substantially the same shape as the exterior perimeter or can be a different shape. The cavity can be symmetrical or asymmetrical. Examples of regular shapes include cylinders, ovals, squares, regular polygons (equilateral triangle, pentagon, hexagon, heptagon, octagon, etc.), symmetrical lobed structures. Examples of asymmetrical shapes include irregular polygons having sides of different sizes, asymmetrical lobed structures, etc. The cavity can have a maximum dimension in the x-y plane (defined by the top surface of the base pad and/or) by the top polishing surface of from 20 or from 30 up to 90, up to 80, up to 70 or up to 60% of the maximum dimension in that plane of the protruding structure. The distance from the exterior perimeter to the cavity can be in the range of at least 0.05, at least 0.1, at least 0.3, at least 0.5, at least 0.7, at least 1, or at least 1.2 mm up to 8, up to 7, up to 6, up to 5, up to 4, up to 3, up to 2, or up to 1.8 mm.

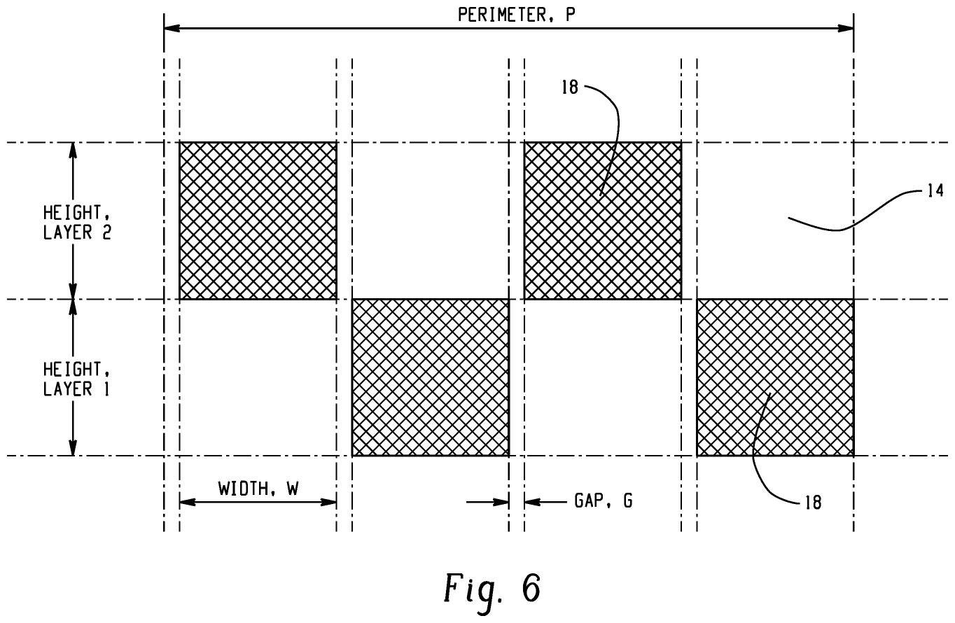

The protruding structures include one or a plurality of openings extending from the exterior perimeter to the cavity(ies). The side openings can be offset from each other in the direction of the x-y plane defined by the surface of the base pad. The side openings can be in alternating regions in the vertical or z-direction relative to the surface of the base pad. FIG. 6 shows a planar view of a portion of the surface of the exterior perimeter surface 14 (i.e. as if the perimeter were laid out on a plane) where rectangular openings 18 are spaced a distance, width, w, in the horizontal direction from each other and in the vertical direction when one opening stops the other begins. The side openings could be other shapes such as parallelograms, triangles, irregular shapes, provided the openings are arranged in a complementary manner such that there is sufficient solid support between the openings to provide mechanical integrity and substantially constant contact area. The side openings can be overlapping in the vertical direction so long as the polishing surface area is a substantially constant contact area. At a given point in the z-direction there can be from 0, from 1, from 2, from 3, from 4, from 5, to 100, to 80, to 60, to 50, to 40, to 30, to 20, to 10 openings between the cavity and the exterior perimeter. The height of the side openings can be from 5, from 10, from 20, from 30% up to 90, up to 80, up to 70, up to 60, up to 50, up to 40% of the total height (from top surface of base pad to initial polishing surface) of the protruding structure. The dimension of the side opening on the exterior perimeter can be the same as but will generally be larger than the dimension of the side opening at the cavity. The dimension of the opening in the x-y plane as defined by the surface of the based pad can be at least 0.1, at least 0.2, at least 0.5 mm, up to 15, up to 10, up to 8, up to 5, up to 4 mm at the exterior perimeter. The dimension of the side openings (wall openings) in the x-y plane at the interior surface will be no greater than the dimension of that opening at the exterior perimeter and will generally be smaller to account for less surface area (smaller distance around perimeter of cavity relative to exterior perimeter of body) on the interior surface than on the exterior of the body. Thus, the interior dimension of side openings at the interior surface can be from 10, from 20, from 30 or from 40 up to 100, up to 90, up to 80, up to 70% of the dimension of that opening at the exterior perimeter.

Polishing surface area (initial and/or subsequent) of a protruding structure can be in the range of from 0.05, from 0.1, or from 0.2 mm² up to 30, up to 25, up to 20, up to 15, up to 10, or up to 5 mm².

A void fraction for the protruding structure can be at least 0.1, at least 0.3, at least, 0.5 up to 0.96, up to 0.95, up to 0.90, up to 0.85, or up to 0.80 where void fraction is calculated the volume of the cavity and openings divided by the volume defined by the exterior of the protruding structure.

The protruding structures can be arranged in any configuration on the working surface. In one embodiment they can be arranged in a hexagonal packing structure oriented in the same direction. In another embodiment they can be arranged in a radial pattern oriented such that one lobe aligns with the radial. The protruding structures do not need to be oriented with any macroscale orientation. Macroscale orientation may be adjusted to achieve desired removal rate, planarization effect, control of defectivity, control of uniformity, and as needed for desired slurry amount.

The protruding structures can be separated from each other—i.e. they do not directly contact each other. The spacing between adjacent protruding structures can, but does not have to be, constant. The structures can be spaced at a distance from center of one protruding structure to center of an adjacent protruding structure, i.e. a pitch, of from 1, from 1.5, or from 2 up to 50, up to 20, up to 10, up to 7, up to 5, or up 4 times a longest dimension from one point on the exterior perimeter to another. The pitch (distance from center of one protruding structure to center of an adjacent protruding structure) can be at least 0.7, at least 1, at least 5, at least 10, or at least 20 mm up to 150, up to 100, up to 50 mm, or up to 30 mm. The distance from the perimeter of one protruding structure to a nearest perimeter of an adjacent protruding structure can be as least 0.02, at least 0.05, at least 0.1, at least 0.5, or at least 1 mm up to 100, up to 50, up to 20, up to 10, or up to 5 mm.

Protruding structures can be formed from any material known to be useful in polishing pads. The composition of the protruding structures may be the same or different from the composition of the base. For example, a protruding structure may comprise or may consist of a polymeric material. Examples of such polymeric materials include polycarbonates, polysulfones, nylons, polyethers, epoxy resins, polyesters, polystyrenes, acrylic polymers, polymethyl methacrylates, polyvinylchlorides, polyvinyl fluorides, polyethylenes, polypropylenes, polybutadienes, polyethylene imines, polyurethanes, polyether sulfones, polyamides, polyether imides, polyketones, epoxies, silicones, copolymers thereof (such as, polyether-polyester copolymers), and combinations or blends thereof. The protruding structure may comprise composite of a polymeric material with other materials. Examples of such composites include polymers filled with carbon or inorganic fillers. According to certain embodiments, protruding structure(s) are made of a material having one or more of the following properties: a Young's modulus as determined, for example, by ASTMD412-16 in the range of at least 2, at least 2.5, at least 5, at least 10, at least 20, at least 50, or at least 100 MPa up to 10, up to 5, or up to 1 gigaPascals (GPa), or up to 900, up to 800, up to 700, up to 600, up to 500, up to 400, or up to 300 MPa; a density of 0.4 or 0.5 to 1.7 or 1.5 or 1.3 g/cm³. The material of the protruding structure can have a compressive modulus as determined by ASTM D3574 in the range of at least 2, at least 2.5, at least 5, at least 10, at least 20, at least 50, or at least 100 MPa up to 10, up to 5, or up to 1 gigaPascals (GPa), or up to 900, up to 800, up to 700, up to 600, up to 500, up to 400, or up to 300 MPa.

The pad may be made by any suitable process. For example, the pad may be made by additive manufacturing by known method and the protruding structures are built up on a provided base of the pad by such additive manufacturing or the entire pad could be made by additive manufacturing.

When a polyurethane is used in the base pad and/or the protruding structure it can be the reaction product of a polyfunctional isocayante and a polyol. For example, a polyisocyante terminated urethane prepolymer can be used. The polyfunctional isocyanate used in the formation of the polishing layer of the chemical mechanical polishing pad of the present invention can be selected from the group consisting of an aliphatic polyfunctional isocyanate, an aromatic polyfunctional isocyanate and a mixture thereof. For example, the polyfunctional isocyanate used in the formation of the polishing layer of the chemical mechanical polishing pad of the present invention can be a diisocyanate selected from the group consisting of 2,4-toluene diisocyanate; 2,6-toluene diisocyanate; 4,4′-diphenylmethane diisocyanate; naphthalene-1,5-diisocyanate; tolidine diisocyanate; para-phenylene diisocyanate; xylylene diisocyanate; isophorone diisocyanate; hexamethylene diisocyanate; 4,4′-dicyclohexylmethane diisocyanate; cyclohexanediisocyanate; and, mixtures thereof. The polyfunctional isocyanate can be an isocyanate terminated urethane prepolymer formed by the reaction of a diisocyanate with a prepolymer polyol. The isocyanate-terminated urethane prepolymer can have 2 to 12 wt %, 2 to 10 wt %, 4-8 wt % or 5 to 7 wt % unreacted isocyanate (NCO) groups. The prepolymer polyol used to form the polyfunctional isocyanate terminated urethane prepolymer can be selected from the group consisting of diols, polyols, polyol diols, copolymers thereof and mixtures thereof. For example, the prepolymer polyol can be selected from the group consisting of polyether polyols (e.g., poly(oxytetramethylene)glycol, poly(oxypropylene)glycol and mixtures thereof); polycarbonate polyols; polyester polyols; polycaprolactone polyols; mixtures thereof; and, mixtures thereof with one or more low molecular weight polyols selected from the group consisting of ethylene glycol; 1,2-propylene glycol; 1,3-propylene glycol; 1,2-butanediol; 1,3-butanediol; 2-methyl-1,3-propanediol; 1,4-butanediol; neopentyl glycol; 1,5-pentanediol; 3-methyl-1,5-pentanediol; 1,6-hexanediol; diethylene glycol; dipropylene glycol; and, tripropylene glycol. For example, the prepolymer polyol can be selected from the group consisting of polytetramethylene ether glycol (PTMEG); ester based polyols (such as ethylene adipates, butylene adipates); polypropylene ether glycols (PPG); polycaprolactone polyols; copolymers thereof; and, mixtures thereof. For example, the prepolymer polyol can be selected from the group consisting of PTMEG and PPG. When the prepolymer polyol is PTMEG, the isocyanate terminated urethane prepolymer can have an unreacted isocyanate (NCO) concentration of 2 to 10 wt % (more preferably of 4 to 8 wt %; most preferably 6 to 7 wt %). Examples of commercially available PTMEG based isocyanate terminated urethane prepolymers include Imuthane® prepolymers (available from COIM USA, Inc., such as, PET-80A, PET-85A, PET-90A, PET-93A, PET-95A, PET-60D, PET-70D, PET-75D); Adiprene® prepolymers (available from Chemtura, such as, LF 800A, LF 900A, LF 910A, LF 930A, LF 931A, LF 939A, LF 950A, LF 952A, LF 600D, LF 601D, LF 650D, LF 667, LF 700D, LF750D, LF751D, LF752D, LF753D and L325); Andur® prepolymers (available from Anderson Development Company, such as, 70APLF, 80APLF, 85APLF, 90APLF, 95APLF, 60DPLF, 70APLF, 75APLF). When the prepolymer polyol is PPG, the isocyanate terminated urethane prepolymer can have an unreacted isocyanate (NCO) concentration of 3 to 9 wt % (more preferably 4 to 8 wt %, most preferably 5 to 6 wt %). Examples of commercially available PPG based isocyanate terminated urethane prepolymers include Imuthane® prepolymers (available from COIM USA, Inc., such as, PPT-80A, PPT-90A, PPT-95A, PPT-65D, PPT-75D); Adiprene® prepolymers (available from Chemtura, such as, LFG 963A, LFG 964A, LFG 740D); and, Andur® prepolymers (available from Anderson Development Company, such as, 8000APLF, 9500APLF, 6500DPLF, 7501DPLF). The isocyanate terminated urethane prepolymer can be a low free isocyanate terminated urethane prepolymer having less than 0.1 wt % free toluene diisocyanate (TDI) monomer content. Non-TDI based isocyanate terminated urethane prepolymers can also be used. For example, isocyanate terminated urethane prepolymers include those formed by the reaction of 4,4′-diphenylmethane diisocyanate (MDI) and polyols such as polytetramethylene glycol (PTMEG) with optional diols such as 1,4-butanediol (BDO) are acceptable. When such isocyanate terminated urethane prepolymers are used, the unreacted isocyanate (NCO) concentration is preferably 4 to 10 wt % (more preferably 4 to 10 wt %, most preferably 5 to 10 wt %). Examples of commercially available isocyanate terminated urethane prepolymers in this category include Imuthane® prepolymers (available from COIM USA, Inc. such as 27-85A, 27-90A, 27-95A); Andur® prepolymers (available from Anderson Development Company, such as, IE75AP, IE80AP, IE 85AP, IE90AP, IE95AP, IE98AP); and, Vibrathane® prepolymers (available from Chemtura, such as, B625, B635, B821).

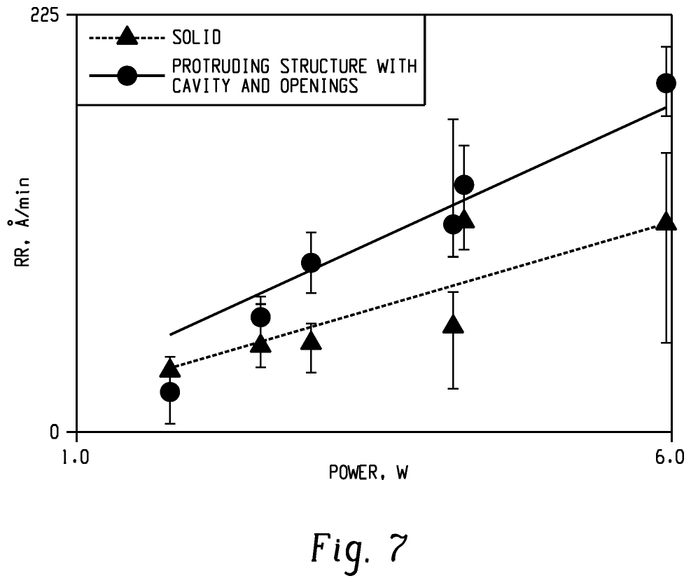

Pads having the protrusions as disclosed herein surprisingly can have improved removal rates as compared to pads having solid protrusions having the same exterior perimeter even though due to the cavity they would have less polishing surface area. For example, two pads were used to polish on a CETR brand 8-inch (20.3 cm) polisher using 2-inch (5.1 cm) tetraethylortho silcate wafers. Klebosol® II 1730, a colloidal silica slurry, was used as the polishing slurry. Standard ellipsometry wafer metrology was utilized to measure pre and post-polish wafer thickness to calculate removal rate. Wafers were polished for 60 seconds before being cleaned and dried prior to measurement. Removal Rate data are presented in FIG. 7. These data show that pads, having a plurality of cylindrical protrusions having an exterior perimeter of 6.28 mm a cavity size of diameter 1 mm and 4 openings at any height with an opening height of 0.2 mm and angle of 22.5 degrees, deliver improved removal rate response compared to a pad having a similar number and spacing solid cylindrical protrusions of the same exterior perimeter and material.

### Method

The polishing pads as disclosed here can be used to polish substrates. For example, the polishing method can include providing a substrate to be polished and then polishing using the pad disclosed herein with the protrusions in contact with the substrate to be polished. The substrate can be any substrate where polishing or planarization is desired. Examples of such substrates include magnetic, optical and semiconductor substrates. The method made be part front end of line or back end of line processing for integrated circuits. For example, the process can be used to remove undesired surface topography and surface defects, such as rough surfaces, agglomerated materials, crystal lattice damage, scratches and contaminated layers or materials. In addition, in damascene processes a material is deposited to fill recessed areas created by one or more steps of photolithography, patterned etching, and metallization. Certain steps can be imprecise—e.g. there can be overfilling of recesses. The method disclosed here can be used to remove material outside the recesses. The process can be chemical mechanical planarization or chemical mechanical polishing both of which can be referred to as CMP. A carrier can hold the substrate to be polished—e.g. a semiconductor wafer (with or without layers formed by lithography and metallization) in contact with the polishing elements of the polishing pad. A slurry or other polishing medium can be dispensed into a gap between the substrate and the polishing pad. The polishing pad and substrate are moved relative to one another—e.g. rotated. The polishing pad is typically located below the substrate to be polished. The polishing pad can rotate. The substrate to be polished can also be moved—e.g. on a polishing track such as an annular shape. The relative movement causes the polishing pad to approach and contact the surface of the substrate.

For example, the method can comprise: providing a chemical mechanical polishing apparatus having a platen or carrier assembly; providing at least one substrate to be polished; providing a chemical mechanical polishing pad as disclosed herein; installing onto the platen the chemical mechanical polishing pad; optionally, providing a polishing medium (e.g. slurry and/or non-abrasive containing reactive liquid composition) at an interface between a polishing portion of the chemical mechanical polishing pad and the substrate; creating dynamic contact between the polishing portion of the polishing pad and the substrate, wherein at least some material is removed from the substrate. The carrier assembly carrier assembly can provide a controllable pressure between the substrate being polished (e.g. wafer) and the polishing pad. The polishing medium can be dispensed onto the polishing pad and drawn into the gap between the wafer and polishing layer. The polishing medium can comprise water, a pH adjusting agent, and optionally one or more of, but not limited to, the following: an abrasive particle, an oxidizing agent, an inhibitor, a biocide, soluble polymers, and salts. The abrasive particle can be an oxide, metal, ceramic, or other suitably hard material. Typical abrasive particles are colloidal silica, fumed silica, ceria, and alumina. The polishing pad and substrate can rotate relative to one another. As the polishing pad rotates beneath the substrate, the substrate can sweep out a typically annular polishing track, or polishing region, wherein the wafer's surface directly confronts the polishing portion of the polishing pad. The wafer surface is polished and made planar by chemical and mechanical action of the polishing layer and polishing medium on the surface. Optionally, the polishing surface of the polishing pad can be conditioned with an abrasive conditioner before beginning polishing. Optionally the method of the present invention, the chemical mechanical polishing apparatus provided further includes a light source and a photosensor (preferably a multisensor spectrograph); and, the chemical mechanical polishing pad provided further includes an endpoint detection window; and, the method further comprises: determining a polishing endpoint by transmitting light from the light source through the endpoint detection window and analyzing the light reflected off the surface of the substrate back through the endpoint detection window incident upon the photosensor. The substrate can have a metal or metallized surface, such as one containing copper or tungsten. The substrate can be a magnetic substrate, an optical substrate and a semiconductor substrate.

This disclosure further encompasses the following aspects.

Aspect 1: A polishing pad useful in chemical mechanical polishing comprising a base pad having a top side, a plurality of protruding structures on the top side of the base pad, each of the protruding structures having a body, where the body has (i) an exterior perimeter surface defining an exterior shape of the protruding structure, (ii) an interior surface defining one or more central cavity and (iii) a top surface defining an initial polishing surface area, wherein the body further has openings in it from the cavity to the exterior perimeter surface.

Aspect 2: The polishing pad of aspect 1 wherein the exterior shape is cylindrical, ellipsoidal, polygonal, of an irregular curved surface.

Aspect 3: The polishing pad of any one of the previous aspects wherein the central cavity has a shape that is cylindrical, ellipsoidal, polygonal, of an irregular curved surface

Aspect 4: The polishing pad of any of the previous aspects comprising two or more cavities.

Aspect 5: The polishing pad of aspect 4 wherein the two or more cavities are defined by the interior surface and one or more separating walls or ribs.

Aspect 6: The polishing pad of any one of aspects 1-3 having one cavity.

Aspect 7: The polishing pad of any of the previous aspects wherein the openings each have a height of at least 5%, preferably at least 10%, more preferably at least 20%, and most preferably at least 30% of a height of the protruding structure.

Aspect 8: The polishing pad of any of the previous aspects wherein each of the openings have a height of no more than 80%, preferably no more than 70%, more preferably no more than 60%, yet more preferably no more than 50%, and most preferably no more than up to 40% of a height of the protruding structure.

Aspect 9: The polishing pad of any of the previous aspects wherein the number of openings at a given level of distance in the z-direction from the surface of the base pad is from 2 to 80, preferably 3 to 60, more preferably 4 to 50, and most preferably 5 to 50.

Aspect 10: The polishing pad of any of the previous aspects having a total void fraction in the range of 0.3 to 0.96, preferably 0.4 to 0.95, more preferably 0.5 to 0.90.

Aspect 11: The polishing pad of any of the previous aspects wherein the base pad and the protruding structure are integral to each other.

Aspect 12: The polishing pad of any of the previous aspects wherein the top surface of a protruding structure is worn down during polishing of a substrate to expose a new polishing surface having a subsequent polishing surface area of the protruding structure that differs from the initial polishing surface area of the protruding structure by less than 25%, preferably less than 10%, more preferably less than 5%.

Aspect 13: The polishing pad of any of the previous aspects where the protruding structures together have a total initial polishing surface area that is the sum of the initial polishing surface area of all protruding structures on the pad and wherein during polishing a new total polishing surface area is exposed that differs from the total initial polishing surface area by less than 25%, preferably less than 10%.

Aspect 14: The polishing pad of any of the previous aspects where each protruding structure has a maximum dimension in a direction parallel to a surface of the base pad of 0.2 to 10 mm, preferably 0.5 to 5 mm, more preferably 0.7 to 2 mm.

Aspect 15: The polishing pad of any of the previous aspects where the exterior perimeter surface represents a protruding structure to the exterior perimeter surface of an adjacent protruding structure are at a distance 0.02 to 40 mm, preferably 0.05 to 20 mm, more preferably 0.1 to 10 mm, and yet more preferably 0.5 to 5 mm.

Aspect 16: The polishing pad of any of the previous aspects where the height of the protruding structures is 0.05 to 3 mm, preferably 0.1 to 2 mm, more preferably 0.5 to 1.5 mm.

Aspect 17: The polishing pad of any of the previous aspects where the distance from the exterior perimeter to the cavity is 0.05 to 8 mm, preferably 0.1 to 7 mm, more preferably 0.3 to 6 mm, yet more preferably 0.5 to 5 mm, still more preferably, 0.7 to 4 mm, even more preferably 1 to 3 mm, and most preferably 0.8 to 2 mm.

Aspect 18: The polishing pad of any of the previous aspects where the effective compressive modulus is 1 to 700 MPa, preferably 5 to 500 MPa, more preferably 10 to 300 MPa.

Aspect 19: The polishing pad of any of the previous aspects wherein the protruding structure is made of a material having a 2 MPa to 10 GPa, preferably 10 MPa to 5 GPa, more preferably 50 to 900 MPa, yet more preferably 100 to 700 MPa.

Aspect 20: The polishing pad of any of the previous aspects wherein the effective compression modulus is 1 to 90%, preferably 5 to 90%, more preferably 10 to 80% and yet more preferably 25 to 70% of the effective compression model of a pad having the same number and pattern of protruding structures of the same material and the same exterior dimensions but without cavity and openings.

Aspect 21: The polishing pad of any of the previous aspects where the cavity has a dimension in a direction parallel to a surface of the base pad of 20 to 90, preferably 20 to 80, more preferably 30 to 70% of a maximum dimension of the protruding structure in a direction parallel to a surface of the base pad.

Aspect 22: A method comprising providing a substrate, polishing the substrate using the polishing pad of any one of the previous aspects.

Aspect 23: A method comprising providing a polishing medium at the interface of the substrate and the polishing pad prior to or during polishing.

The compositions, methods, and articles can alternatively comprise, consist of, or consist essentially of, any appropriate materials, steps, or components herein disclosed. The compositions, methods, and articles can additionally, or alternatively, be formulated to be devoid, or substantially free, of any materials (or species), steps, or components, that are otherwise not necessary to the achievement of the function or objectives of the compositions, methods, and articles.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g. “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”). “Combinations” is inclusive of blends, mixtures, alloys, reaction products, and the like. The terms “first,” “second,” and the like, do not denote any order, quantity, or importance, but rather are used to distinguish one element from another. The terms “a” and “an” and “the” do not denote a limitation of quantity and are to be construed to cover both the singular and the plural, unless otherwise indicated herein or clearly contradicted by context. “Or” means “and/or” unless clearly stated otherwise. Reference throughout the specification to “some embodiments”, “an embodiment”, and so forth, means that an element described in connection with the embodiment is included in at least one embodiment described herein, and may or may not be present in other embodiments. In addition, it is to be understood that the described elements may be combined in any suitable manner in the various embodiments. A “combination thereof” is open and includes any combination comprising at least one of the listed components or properties optionally together with a like or equivalent component or property not listed.

Unless specified to the contrary herein, all test standards are the most recent standard in effect as of the filing date of this application, or, if priority is claimed, the filing date of the earliest priority application in which the test standard appears.

1-8. (canceled)

9. A method comprising
providing a substrate,
polishing the substrate with a polishing pad useful in chemical mechanical polishing comprising
a base pad having a top side,
a plurality of protruding structures on the top side of the base pad, each of the protruding structures having a body, where the body has (i) an exterior perimeter surface defining an exterior shape of the protruding structure, (ii) an interior surface defining a central cavity and (iii) a top surface defining an initial polishing surface area, wherein the body further has openings in it from the central cavity to the exterior perimeter surface and dimensions of the openings of the exterior perimeter surface are larger than dimensions of openings to the central cavity; and wherein at least some material is removed from the substrate.

10. The method of claim 9, wherein a polishing medium is present at an interface between the substrate and the polishing pad during polishing.

11. The method of claim 10, wherein the polishing medium comprises colloidal silica, fumed silica, ceria, or alumina.

12. The method of claim 9, wherein the top surface is worn down during polishing of a substrate to expose a new polishing surface having a subsequent polishing surface area and the body and openings are such that the initial polishing surface area differs from the subsequent polishing surface area by less than 25% based on the initial polishing surface area.

13. The method of claim 9, wherein the openings are offset from each other in vertical and horizontal directions.

14. The method of claim 9, wherein a Young's modulus of the protruding structure is higher than a Young's modulus of the base pad.

15. The method of claim 9, wherein the protruding structure is characterized by a void fraction of 0.1 to 0.96.

16. The method of claim 9, wherein the substrate comprises copper or tungsten.
